(19) United States
(12) Patent Application Publication
(10) Pub. No.: US 2025/0098138 A1
(43) Pub. Date: Mar. 20, 2025

(54) MEMORY DEVICES WITH A BACKSIDE READ WORD LINE

(71) Applicant: Taiwan Semiconductor Manufacturing Company, Ltd., Hsin-Chu (TW)

(72) Inventors: Ping-Wei Wang, Hsin-Chu (TW); Feng-Ming Chang, Hsinchu County (TW); Jui-Lin Chen, Taipei City (TW); Yu-Bey Wu, Hsinchu City (TW)

(21) Appl. No.: 18/469,911

(22) Filed: Sep. 19, 2023

(51) Int. Cl. H10B 10/00

(52) U.S. Cl. CPC H10B 10/125

(57) ABSTRACT

Semiconductor structures and methods are provided. An exemplary semiconductor structure according to the present disclosure includes a two-port static random access memory (SRAM) cell having a write port portion and a read port portion electrically coupled to the write port portion. The read port portion includes a transistor having a gate structure. The semiconductor structure also includes a first plurality of metal lines comprising a write bit line and a complementary write bit line are positioned at a first interconnect layer disposed over the gate structure and a read word line positioned at a second interconnect layer and electrically coupled to the gate structure, the second interconnect layer is disposed under the gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, aggressive scaling down of IC dimensions has resulted in densely spaced source/drain features and gate structures, and densely spaced source/drain contacts and gate vias formed thereover. In some IC circuits (e.g., memory devices), multilayer interconnect structure providing metal tracks (metal lines) for interconnecting power lines and signal lines in and between memory cells of the memory devices are formed over transistors of the memory cells. With ever-decreasing device sizes and densely spaced transistors, some metal tracks (e.g., landing pads for signal lines) are formed to have reduced dimensions, which may lead to increased parasitic resistance, increased parasitic capacitance, high process risk, and/or poor connection; some signal lines may be arranged in a metal line that is far away from the memory cell, which may degrade the speed of the memory devices. All those issues present performance, yield, and cost challenges. Therefore, while existing memory devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC chip, in portion or entirety, according to various aspects of the present disclosure.

FIG. 1B is a diagrammatic plan view of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC chip of FIG. 1, according to various aspects of the present disclosure.

FIG. 3 illustrates a cross-sectional view of various layers of a memory device, in portion or entirety, according to various aspects of the present disclosure.

FIGS. 4, 5, 6, 7, and 8 illustrate different portions of a layout of a memory device having the SRAM cell of FIG. 2, according to various aspects of the present disclosure.

FIG. 9 illustrates a cross-sectional view of the memory device taken along line A-A shown in FIGS. 4 and 6, in portion or entirety, according to various aspects of the present disclosure.

FIG. 10 illustrates a fragmentary cross-sectional view of the memory device taken along line B-B shown in FIG. 9, according to various aspects of the present disclosure.

FIG. 11 illustrates a first alternative layout of the memory device, in portion or entirety, according to various aspects of the present disclosure.

FIG. 12 illustrates a second alternative layout of the memory device, in portion or entirety, according to various aspects of the present disclosure.

FIG. 13 illustrates a third alternative layout of the memory device, in portion or entirety, according to various aspects of the present disclosure.

FIG. 14 illustrates a layout of various layers of another memory device, in portion or entirety, according to various aspects of the present disclosure.

FIG. 15 illustrates a first alternative layout of various layers of the memory device in FIG. 14, in portion or entirety, according to various aspects of the present disclosure.

FIG. 16 illustrates a second alternative layout of various layers of the memory device in FIG. 14, in portion or entirety, according to various aspects of the present disclosure.

FIG. 17 illustrates a third alternative layout of various layers of the memory device in FIG. 14, in portion or entirety, according to various aspects of the present disclosure.

FIG. 18 is a circuit diagram of another memory cell that can be implemented in the IC chip of FIG. 1, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

IC manufacturing process flow may be typically divided into three categories: front-end-of-line (FEOL) processes, middle-end-of-line (MEOL) processes, and back-end-of-line (BEOL) processes. FEOL processes generally encompasses processes related to fabricating IC devices, such as transistors. For example, FEOL processes may include forming isolation features, gate structures, and source/drain features. Source/drain feature(s) may refer to a source or a drain, individually or collectively dependent upon the context. MEOL processes generally encompasses processes related to fabricating contacts to conductive features of the IC devices, such as gate vias to the gate structures and/or source/drain contacts to the source/drain features. BEOL processes generally encompasses processes related to fabricating a multilayer interconnect structure that interconnects IC features fabricated by FEOL and MEOL process, thereby enabling operation of the IC devices. Features fabricated by FEOL processes may be referred to as FEOL features. Features fabricated by MEOL processes may be referred to as MEOL features. Features fabricated by BEOL processes may be referred to as BEOL features.

Multi-gate devices, such as fin field-effect transistors (FinFETs) and multi-bridge-channel (MBC) transistors, have been introduced in an effort to improve gate control by increasing gate-channel coupling, reduce OFF-state current, and reduce short-channel effects (SCEs). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, or other nanostructures and for that reasons, an MBC transistor may also be referred to as a nanostructure transistor.

To perform satisfactory functions, static random-access memory (SRAM) cells are electrically coupled to signal lines and power lines. For example, a two-port SRAM cell formed of seven transistors (i.e., 7T SRAM cell) is electrically coupled to signal lines including a read-port bit line R_BL, a read-port word line R_WL, a write-port bit line W_BL, a write-port word line W_WL, and power lines configured to provide predetermined voltages VDD and VSS (may be referred to as VDD line and VSS line, respectively). In some exiting technologies, all those signal lines and power lines and related landing pads are formed in interconnect layers that are disposed over a frontside of the SRAM cell(s). In the present disclosure, landing pads generally refer to metal lines in interconnect layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or power lines. As described above, aggressive scaling down of IC dimensions has resulted in densely spaced transistors and thus densely spaced BEOL features with reduced dimensions, which may lead to increased parasitic resistance, increased parasitic capacitance, increased process risk, and/or reduced speed.

The present disclosure provides memory devices including a read-port word line that is formed under a backside of the SRAM cell rather than over a frontside of the SRAM cell to relax process windows and limits on SRAM performance optimization. In an embodiment, the memory device includes a 7T SRAM cell having a write portion and a read portion, and a transistor of the read portion having a first source/drain feature coupled to write portion, a second source/drain feature coupled to a read-port bit line, and a gate structure electrically coupled to a read-port word line. In a cross-sectional view, the read-port bit line is disposed directly over the second source/drain feature, and the read-port word line is disposed directly under the gate structure. Forming the read-port word line under the gate structure would release room that would be otherwise occupied by a frontside landing pad for a frontside read-port bit line, thereby increasing design flexibility of metal lines that are disposed over the SRAM cell. Forming the read-port word line under the gate structure may also enable the read-port bit line to be formed at the M0 level to increase the speed of the memory device.

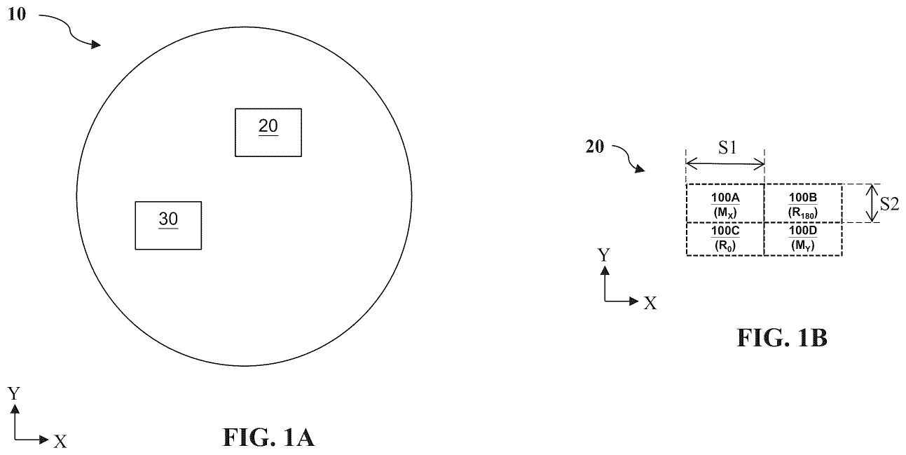

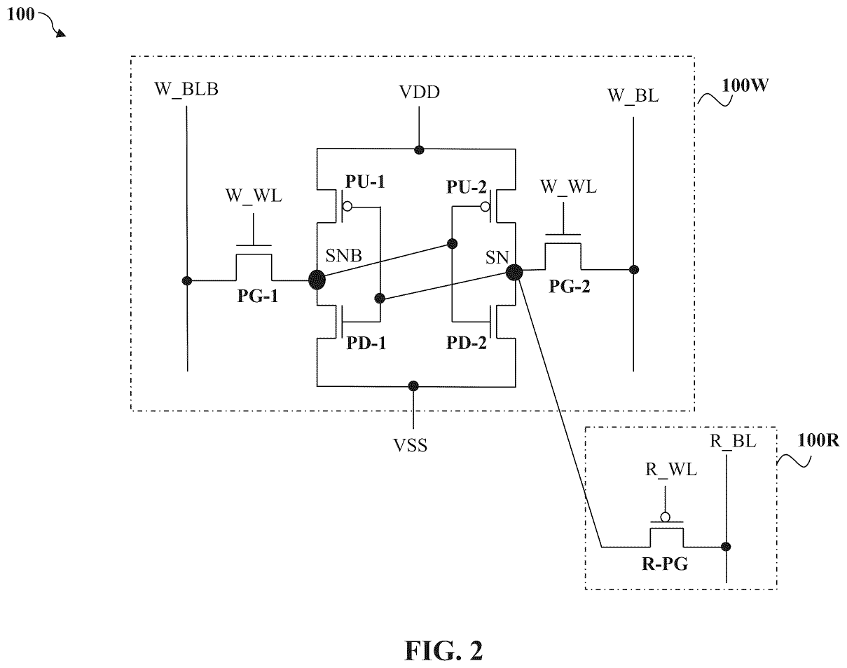

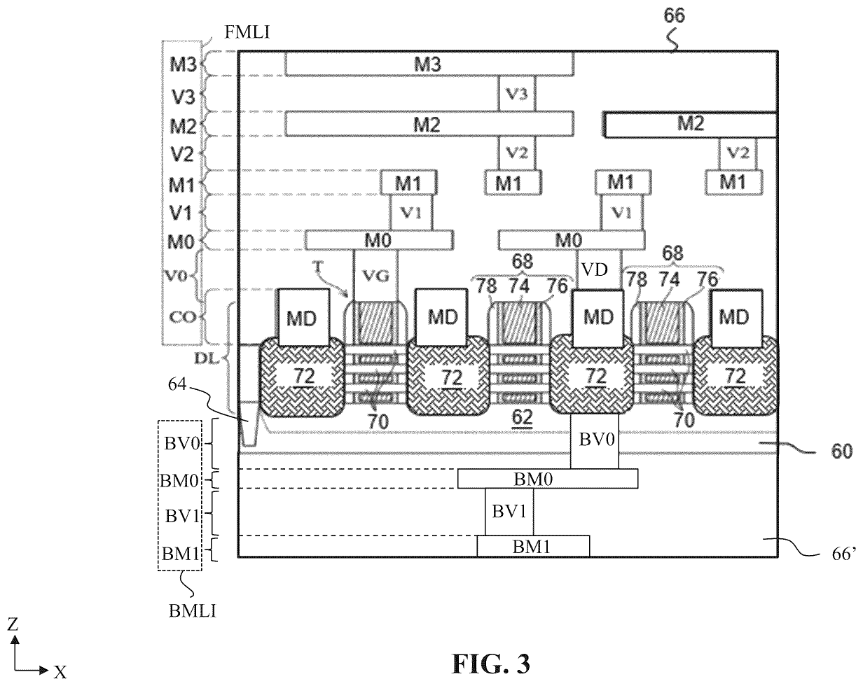

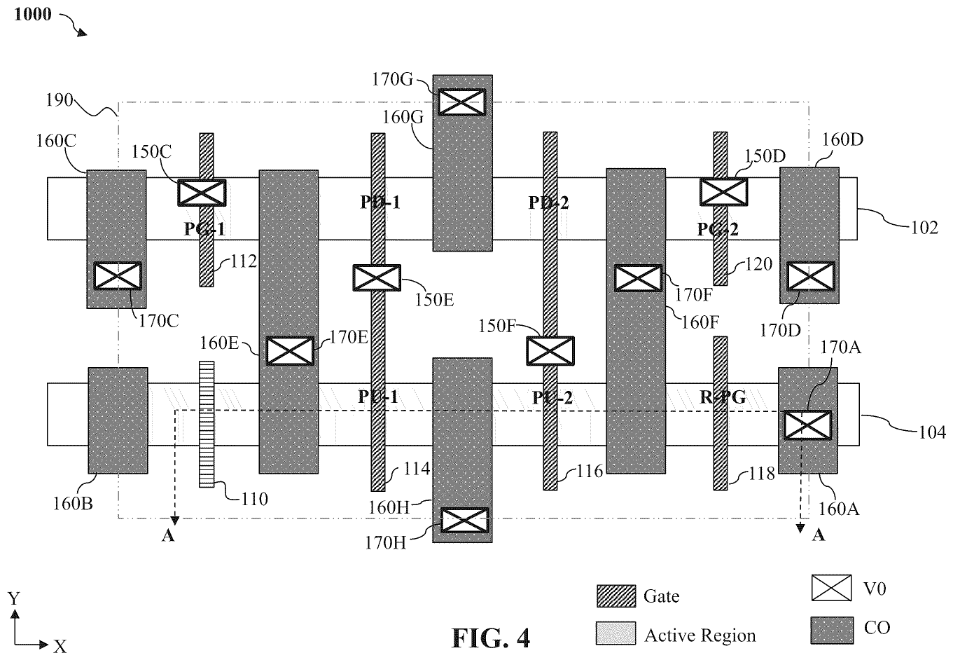

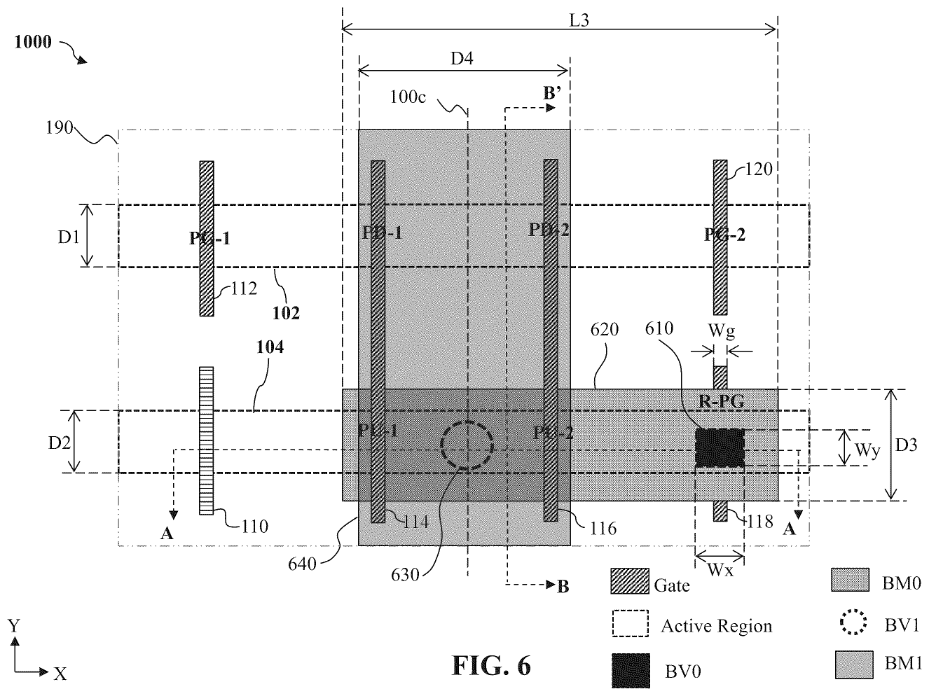

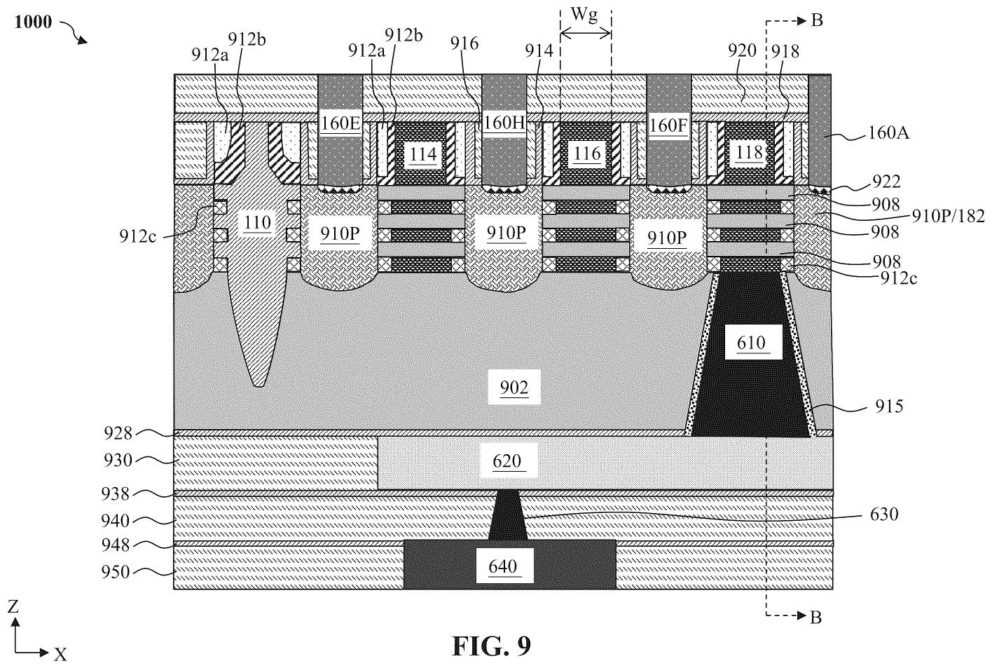

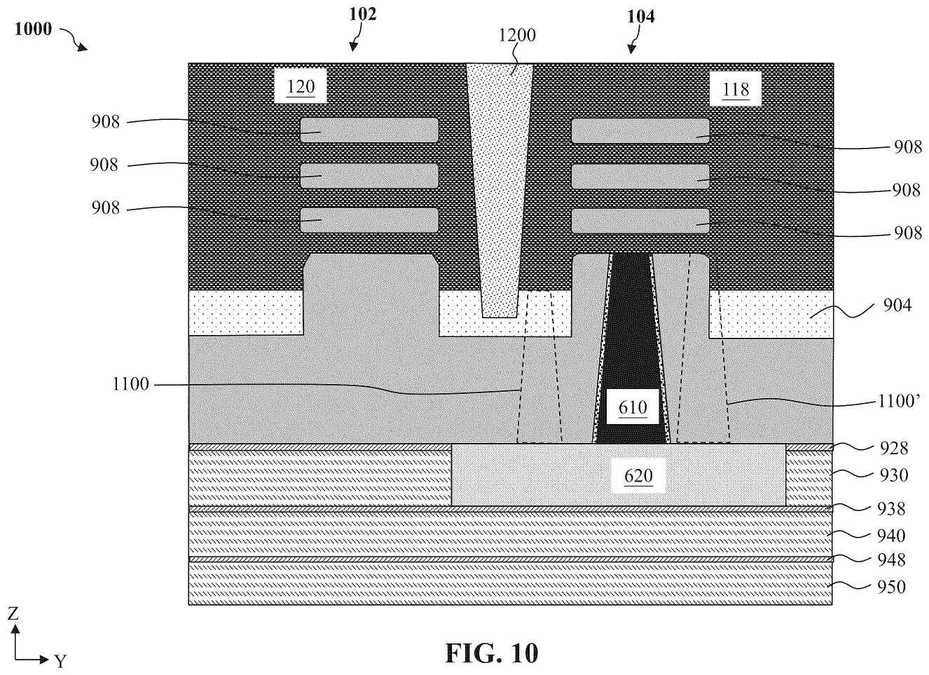

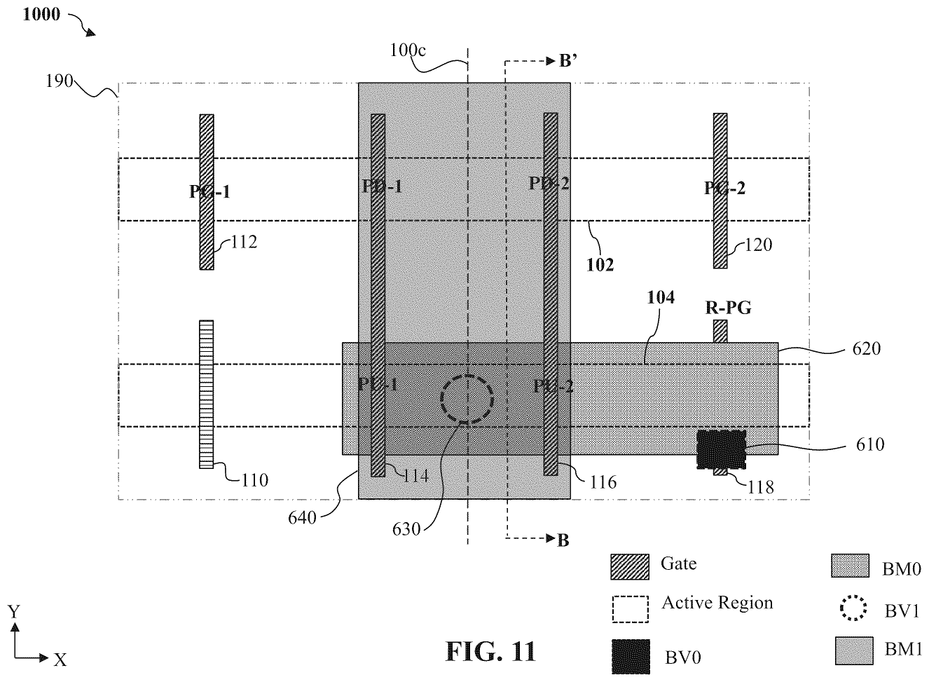

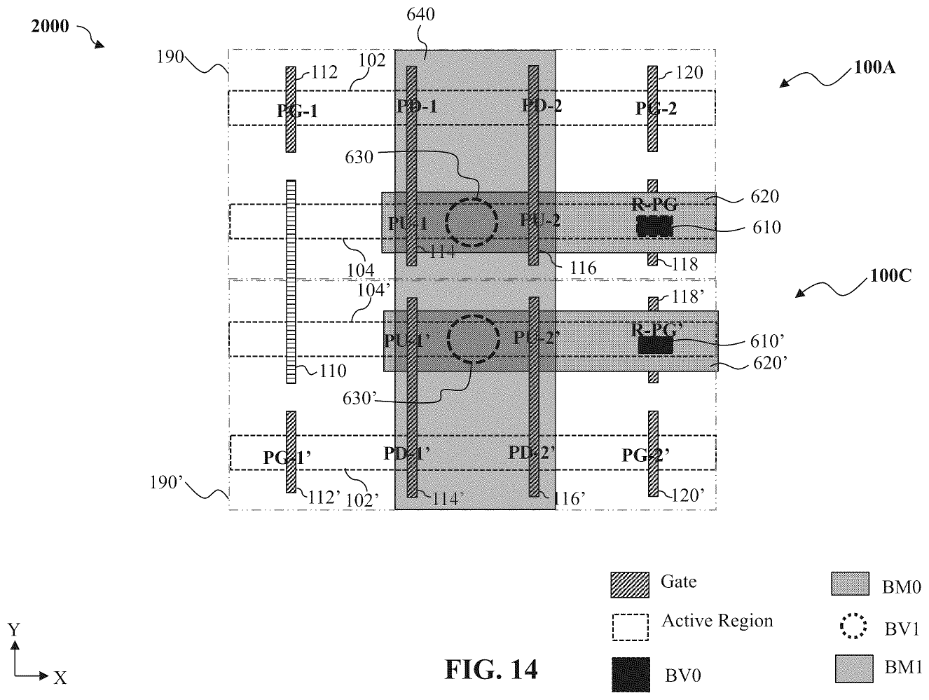

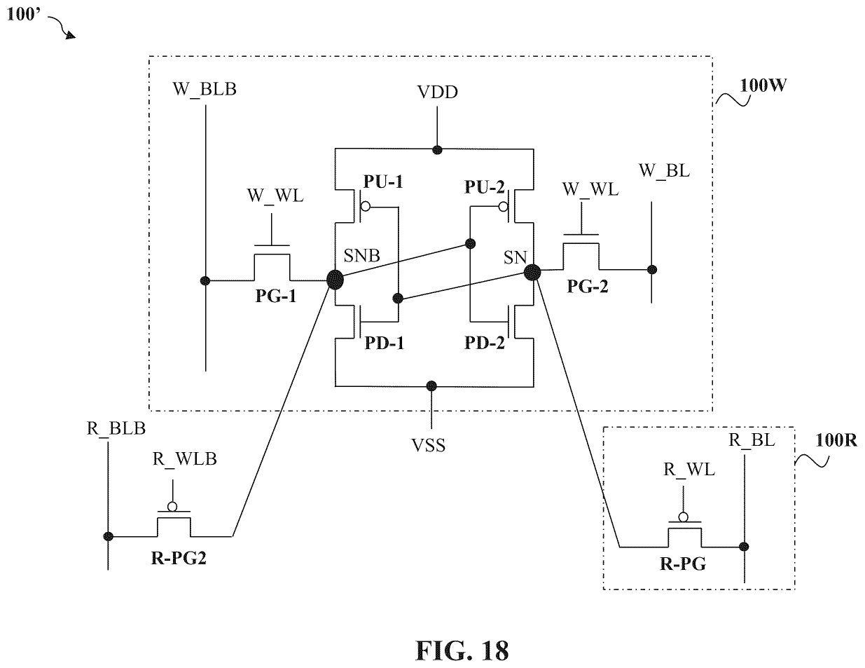

The various aspects of the present disclosure will now be described in more detail with reference to the figures. In that regard, FIG. 1A is a diagrammatic plan view of an exemplary IC chip. FIG. 1B is a diagrammatic plan view of an array of memory cells, such as static random-access memory (SRAM) cells, in portion or entirety, according to various aspects of the present disclosure. FIG. 2 is a circuit diagram of a 7T SRAM cell that can be implemented in the IC chip of FIG. 1. FIG. 3 illustrates a cross-sectional view of various layers of a memory device, in portion or entirety, according to various aspects of the present disclosure. FIGS. 4, 5, 6, 7, and 8 illustrate different portions of a layout of a memory device 1000 having the 7T SRAM cell, according to various aspects of the present disclosure. FIG. 9 illustrates a cross-sectional view of the memory device 1000 taken along line A-A shown in FIGS. 4 and 6, in portion or entirety, according to various aspects of the present disclosure. FIG. 10 illustrates a cross-sectional view of the memory device 1000 taken along line B-B shown in FIG. 9, in portion or entirety, according to various aspects of the present disclosure. FIGS. 11-13 illustrate alternative layouts of the memory device, in portion or entirety, according to various aspects of the present disclosure. FIGS. 14-18 each illustrate a layout of various layers of another memory device 2000, in portion or entirety, according to various aspects of the present disclosure. FIG. 18 is a circuit diagram of another memory cell that can be implemented in the IC chip of FIG. 1, according to various aspects of the present disclosure. For avoidance of doubts, the X-axis, Y-axis and Z-axis in the figures are perpendicular to one another and are used consistently throughout the present disclosure. Throughout the present disclosure, like reference numerals denote like features unless otherwise excepted.

Referring to FIG. 1A, the present disclosure provides an IC chip 10 formed over a substrate and includes at least an array 20 of memory cells. The array 20 may include static random-access memory (SRAM) cells, dynamic random-access memory (DRAM) cells, non-volatile random-access memory (NVRAM) cells, flash memory cells, other suitable memory cells, or combinations thereof. The IC chip 10 may further include a number of other components, such as an array 30 of standard logic (STD) cells configured to provide various standard logic devices, such as inverter, AND, NAND, OR, XOR, NOR, other suitable devices, or combinations thereof. Additionally, the IC chip 10 may include various passive and active microelectronic devices, such as resistors, capacitors, inductors, diodes, bipolar transistors, high voltage transistors, high frequency transistors, other suitable devices, or combinations thereof. Additional features can be added to the IC chip 10 and some of the features described below can be replaced, modified, or eliminated in other embodiments of the IC chip 10.

In the present embodiments, referring to FIG. 1B, the array 20 includes a number of SRAM cells (such as SRAM cells 100A, 100B, 100C, and 100D), which generally provide memory or storage capable of retaining data when power is applied. As such, the array 20 is hereafter referred to as an SRAM array 20. The array 20 may also be referred to as a memory device 20 or a semiconductor structure 20. In the present disclosure, the memory device 20 may include one or more SRAM cells and frontside and backside interconnect layers associated with the one or more SRAM cells. In the present embodiments, each of the SRAM cells 100A-100D includes one or more GAA transistors to be discussed in detail below.

In the present embodiments, still referring to FIG. 1B, the SRAM cells 100A, 100B, 100C, and 100D, together defining a two-by-two grid, exhibit mirror and/or rotational symmetry with respect to each other. For example, using the SRAM cell 100C as a reference (denoted “R₀”), a layout of the SRAM cell 100A (denoted “M_{X}”) is a mirror image of a layout of the SRAM cell 100C with respect to the X-axis. Similarly, a layout of the SRAM cell 100B is a mirror image of the layout of the SRAM cell 100A, and a layout of the SRAM cell 100D (denoted “M_{Y}”) is a mirror image of the layout of the SRAM cell 100C, both with respect to the Y-axis. In other words, the layout of the SRAM cell 100B (denoted “R₁₈₀”) is symmetric to the layout of the SRAM cell 100C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 100A-100D are substantially the same in size, i.e., having substantially the same cell width S1 along the X-axis and cell height S2 along the Y-axis. As such, each of the SRAM cells 100A-100D may hereafter be referred to as the SRAM cell 100 for purposes of simplicity.

FIG. 2 illustrates an example circuit schematic for a two-port SRAM cell 100 that includes seven transistors (7T). The two-port SRAM cell 100 includes a write port portion 100W. In the present embodiments, the write port portion 100W includes pull-up transistors PU-1, PU-2, pull-down transistors PD-1, PD-2, and pass-gate transistors PG-1, PG-2. In the illustrated embodiment, transistors PU-1 and PU-2 are P-type transistors, and transistors PG-1, PG-2, PD-1, and PD-2 are N-type transistors. The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power line configured to provide a first voltage VDD (this power line may be referred to as a VDD line), and the sources of the pull-down transistors PD-1 and PD-2 are coupled to a power line configured to provide a second voltage VSS (this power line may be referred to as a VSS line), which may be an electrical ground in some embodiments.

The storage node SN of the data latch is coupled to a bit line W_BL of the write port portion 100W (may be referred to as a write bit line W_BL or a write-port bit line W_BL) through the pass-gate transistor PG-2, and the complementary storage node SNB is coupled to a complementary bit line W_BLB of the write port portion 100W (may be referred to as a complementary write bit line W_BLB or a complementary write-port bit line W_BLB) through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write port portion 100W (may be referred to as a write word line W_WL or a write-port word line W_WL).

The two-port SRAM cell 100 also includes a read port portion 100R coupled to the write port portion 100W. The read port portion 100R of the SRAM cell 100 includes a read-port pass-gate transistor R-PG. One source/drain terminal of the read-port pass-gate transistor R-PG is electrically coupled to a bit line R_BL of the read port portion 100R. The bit line of the read port portion 100R may be referred to as a read-port bit line R_BL or a read bit line R_BL. The other source/drain terminal of the read-port pass-gate transistor R-PG is electrically coupled to the storage node SN (or to the gates of the transistors PU-1 and PD-1). The gate of the read-port pass-gate transistor R-PG is coupled to a word line R_WL of the read port portion 100R. The word line R_WL of the read port portion 100R may be referred to as a read word line R_WL or a read-port word line R_WL. In the illustrated embodiment, the transistor R-PG is a P-type transistor. That is, in the two-port SRAM cell 100, the pass-gate transistors in the write port portion 100W are N-type transistors, and the pass-gate transistor in read port portion 100R is a P-type transistor.

FIG. 3 is a fragmentary diagrammatic cross-sectional view of various layers (levels) that can be fabricated over and under a semiconductor substrate (or wafer) 60 to form a portion of a memory device, such as IC chip 10 of FIG. 1, according to various aspects of the present disclosure. As represented in FIG. 3, the various layers include a device layer DL, a frontside multilayer interconnect structure FMLI disposed over the device layer DL, and a backside multilayer interconnect structure BMLI disposed under the device layer DL.

Device layer DL includes devices (e.g., transistors, resistors, capacitors, and/or inductors) and/or device components (e.g., doped wells, gate structures, and/or source/drain features). In embodiments represented by FIG. 3, the device layer DL includes substrate 60, doped regions 62 (e.g., n-wells and/or p-wells) disposed in substrate 60, isolation feature 64, and transistors T. In the depicted embodiment, transistors T include suspended channel layers 70 and gate structures 68 disposed between source/drain features 72, where gate structures 68 wrap and/or surround suspended channel layers 70. Each gate structure 68 has a metal gate stack formed from a gate electrode 74 disposed over a gate dielectric layer 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers. In the depicted embodiment, the multilayer interconnect structure FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the multilayer interconnect structure FMLI with N as an integer ranging from 1 to 10. Each level of multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In embodiments represented by FIG. 3, the CO level includes source/drain contacts MD disposed in the dielectric structure 66. The source/drain contacts MD may be formed on and in direct contact with silicide layers disposed directly on the source/drain features 72. The V0 level includes gate vias VG disposed on the gate structures and source/drain contact vias VD disposed on the source/drain contacts MD, where gate vias VG connect gate structures to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines.

In the depicted embodiment, the multilayer interconnect structure BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level and BM1 level may be referred to as BV0 vias, BV1 vias, and BM1 metal lines, respectively. The present disclosure contemplates multilayer interconnect structure BMLI having more or less interconnect layers and/or levels, for example, a total number of M interconnect layers (levels) of the multilayer interconnect structure BMLI with M as an integer ranging from 1 to 10. Each level of multilayer interconnect structure BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure BMLI are collectively referred to as a dielectric structure 66′. In some embodiments, conductive features at a same level of multilayer interconnect structure BMLI, such as BM0 level, are formed simultaneously. In some embodiments, conductive features at a same level of multilayer interconnect structure BMLI have top surfaces that are substantially planar with one another and/or bottom surfaces that are substantially planar with one another.

In embodiments represented by FIG. 3, the BV0 level includes vias BV0 formed under the device layer DL. For example, the vias BV0 may include one or more backside source/drain vias formed directly under the source/drain features of the device layer DL and coupled to those source/drain features by way of a silicide layer. The vias BV0 may include one or more backside gate vias formed directly under and in direct contact with the gate structure(s) of the device layer DL. The BM0 level includes BM0 metal lines formed under the BV0 level. The backside gate vias connect gate structures to BM0 metal lines, and the backside source/drain vias connect source/drain features to BM0 metal lines. The BV1 level includes BV1 vias disposed in the dielectric structure 66′, where BV1 vias connect BM0 metal lines to BM1 metal lines. The BM1 level includes BM1 metal lines formed under the BV1 level.

FIG. 3 has been simplified for the sake of clarity to better understand the inventive concepts of the present disclosure. Additional features can be added in the various layers of the memory, and some of the features described can be replaced, modified, or eliminated in other embodiments of the memory. FIG. 3 is merely an example and may not reflect an actual cross-sectional view of the IC chip 10 and/or the memory device 1000 that is described in further detail below.

In embodiments represented in FIGS. 2-10, the SRAM cell 100 of the memory device 1000 is electrically coupled to the write-port bit line W_BL, the complementary write-port bit line W_BLB, the write-port word line W_WL, the read-port word line R_WL, the read-port bit line R_BL, the VSS line, and the VDD line. In the present embodiments, the write-port bit line W_BL and the complementary write-port bit line W_BLB are positioned at the M2 level, and various landing pads are formed between the M2 level and the device layer DL to provide conductive paths. The write-port word line W_WL is positioned in the M1 level, and various landing pads are formed between the M1 level and the device layer DL to provide conductive paths. The VSS line and VDD line, and the read-port bit line R_BL are positioned at the M0 level, and various conductive features are provided at the CO level and the V0 level to provide conductive paths. In the present embodiments, as described above, to relax process windows for forming SRAM cells and conductive features (e.g., landing pads) formed over the SRAM cells and relax limits on SRAM performance optimization, the read-port word line R_WL is positioned under the device layer DL of the SRAM cell 100. Various landing pads are formed between the read-port word line and the device layer DL to provide conductive paths. That is, the read-port word line R_WL is located under the backside of the SRAM cell 100, and some other signal lines and power lines such as the read-port bit line R_BL, the VSS line, and the VDD line and associated landing pads are formed over the frontside of the SRAM cell 100.

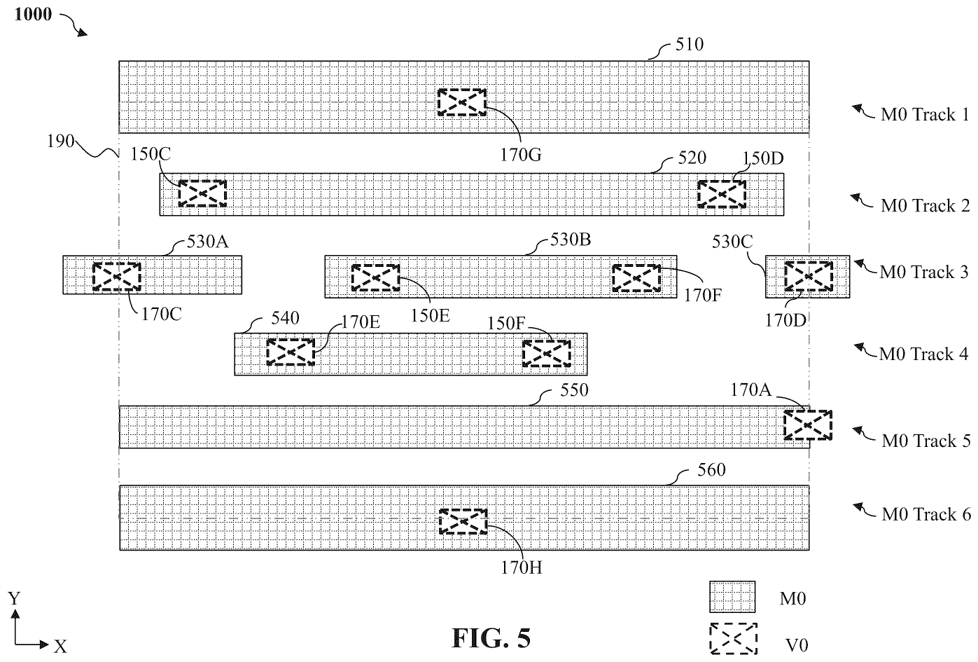

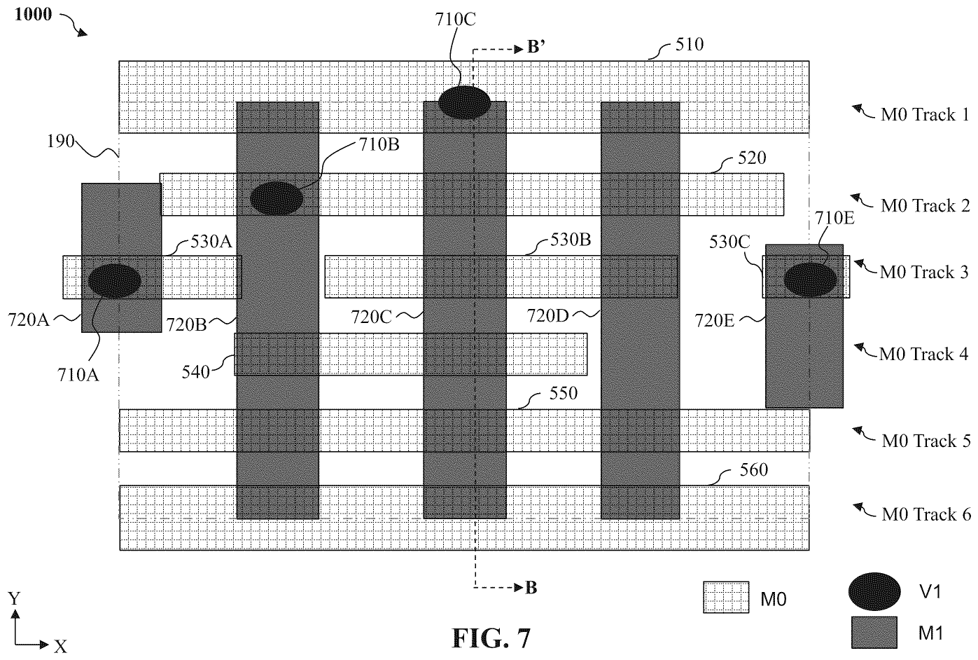

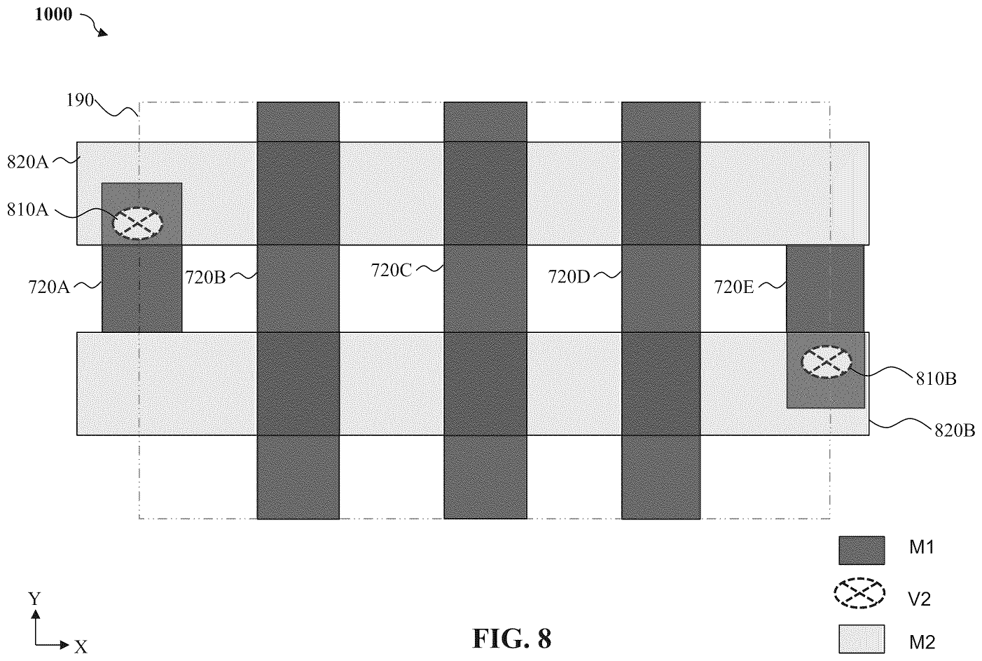

FIGS. 4, 5, 6, 7, and 8 illustrate fragmentary portions of a layout of a memory device 1000 including the two-port SRAM cell 100 of FIG. 2, in accordance with some embodiments of the present disclosure. More specifically, FIG. 4 illustrates a fragmentary portion of a layout of the device layer DL, CO level, and V0 level of the memory device 1000, FIG. 5 illustrates a fragmentary portion of the layout of the V0 level and M0 level of the memory device 1000, FIG. 6 illustrates a fragmentary portion of a layout of the device layer DL, BV0 level, BM0 level, BV1 level, and BM1 level of the memory device 1000, FIG. 7 illustrates a fragmentary portion of a layout of the M0 level, V1 level, and M1 level of the memory device 1000, and FIG. 8 illustrates a fragmentary portion of a layout of the M1 level, V2 level, and M2 level of the memory device 1000. FIG. 9 illustrates a fragmentary cross-sectional view of the memory device taken along line A-A shown in FIGS. 4 and 6, in accordance with some embodiments of the present disclosure. FIG. 10 illustrates a fragmentary cross-sectional view of the memory device taken along line B-B shown in FIG. 9, in accordance with some embodiments of the present disclosure.

Reference is first made to FIG. 4. At the device layer DL, the two-port SRAM cell 100, which is a portion of the memory device 1000, includes active regions 102 and 104 over a substrate 902 (shown in FIG. 9). In embodiments represented by FIG. 4, the active regions 102 and 104 each extend lengthwise along the X-axis and spaced apart from each other along the Y-axis by an isolation feature 904 (e.g., shallow trench isolation (STI) feature, shown in FIG. 10). In the present embodiments, the active region 102 is a three-dimensional fin-like active region (hereafter referred to as an N-type fin 102) disposed in a doped region or well (e.g., P-well, not illustrated) and configured to provide channel regions of N-type transistors, such as a pull-down transistor or a pass-gate transistor, and the active region 104 is a three-dimensional fin-like active region (hereafter referred to as P-type fin 104) disposed in another doped region (e.g., N-well, not illustrated) and configured to provide channel regions of P-type transistors, such as pull-up transistors. In an embodiment, each of the N-type fin 102 and the P-type fin 104 includes a set of vertically stacked semiconductor layers (e.g., semiconductor layers 908 shown in FIG. 9) or nanostructures.

Still referring to FIG. 4, the SRAM cell 100 also includes gate structures, such as gate structures 112, 114, 116, 118 and 120, oriented lengthwise along the Y-axis and disposed over the N-type fin 102 and/or the P-type fin 104 to form various transistors. Each of the gate structures 112, 114, 116, 118 and 120 traverses a channel region of the N-type fin 102 and/or a channel region of the P-type fin 104. In the depicted embodiments, referring to FIG. 4 as an example, the gate structure 112 engages the N-type fin 102 to form the pass-gate transistor PG-1. The gate structure 114 engages the N-type fin 102 and the P-type fin 104 to form the pull-down transistor PD-1 and the pull-up transistor PU-1, respectively. The gate structure 116 engages the N-type fin 102 and the P-type fin 104 to form the pull-down transistor PD-2 and the pull-up transistor PU-2, respectively. The gate structure 118 engages the P-type fin 104 to form the read-port pass-gate transistor R-PG. The gate structure 120 engages the N-type fin 102 to form the pass-gate transistor PG-2. In an embodiment, the gate structure 118 and the gate structure 120 are portions of a continuous gate structure similar to the gate structure 114/116. To fulfill desired functions, an isolation structure (e.g., isolation structure 1200 shown in FIG. 10) may be formed to cut the continuous gate structure into two electrically and physically isolated portions (i.e., the gate structures 118 and 120). That is, sidewalls of the gate structures 118 and 120 are aligned along the Y-axis. In the present embodiments, the pull-up transistors PU-1, PU-2, and the read-port pass-gate transistor R-PG are P-type GAA transistors; the pull-down transistors PD-1 and PD-2, the pass-gate transistor PG-1, and PG-2 are N-type GAA transistors. The area utilization at the device layer DL of the SRAM cell 100 is considered efficient as there is only one unit area not utilized for forming a functional transistor but hosting an intersection of a dielectric feature 110 and an active region instead. A boundary 190 of the two-port SRAM cell 100 is illustrated using broken lines. It is noted that at least some of the active regions 102, 104 and gate structures 112, 114, 116, 118 and 120 may extend beyond the illustrated boundary 190, since these active regions and gate structures may also form components of other adjacently located SRAM cells as well.

Still referring to FIG. 4, the memory device 1000 includes conductive features at the CO level and V0 level formed over the SRAM cell 100. At the V0 level, a gate via 150C is formed on the gate structure 112 of the pass-gate transistor PG-1 and is configured to electrically connect the gate structure 112 of the pass-gate transistor PG-1 to the write-port word line W_WL positioned at a higher metal level. A gate via 150D is formed on the gate structure 120 of the pass-gate transistor PG-2 and is configured to electrically connect the gate structure 120 of the pass-gate transistor PG-2 to the write-port word line W_WL positioned at a higher metal level. A gate via 150E is formed on the gate structure 114 and electrically connects the gate structure 114 to the storage node (SN) positioned at a higher metal level. A gate via 150F is formed on the gate structure 116 and electrically connects the gate structure 116 to the complementary storage node (SNB) positioned at a higher metal level. It is noted that, at the V0 level, there is no gate via formed directly on the gate structure 118 of the read-port pass-gate transistor R-PG.

Still referring to FIG. 4, at the CO level and V0 level, a source/drain contact 160A and a source/drain contact via 170A landing thereon electrically connect a source region of the read-port pass-gate transistor R-PG to the read-port bit line R_BL positioned at a higher metal level. The memory device 1000 includes a dummy source/drain contact 160B adjacent to the dielectric feature 110 and staying electrically floating, as there is no corresponding source/drain contact via landing thereon. A source/drain contact 160C and a source/drain contact via 170C landing thereon electrically connect a source region of the pass-gate transistor PG-1 to the complementary write-port bit line (W_BLB) positioned at a higher metal level. A source/drain contact 160D and a source/drain contact via 170D landing thereon electrically connect a source region of the pass-gate transistor PG-2 to the write-port bit line (W_BL) positioned at a higher metal level. A source/drain contact 160E and a source/drain contact via 170E landing thereon electrically connect a common drain region of the pass-gate transistor PG-1 and the pull-down transistor PD-1 together with a drain region of the pull-up transistor PU-1 to the complementary storage node (SNB) positioned at a higher metal level. A source/drain contact 160F and a source/drain contact via 170F landing thereon electrically connect a common drain region of the pass-gate transistor PG-2 and the pull-down transistor PD-2 together with a common drain region of the pull-up transistor PU-2 and the read-port pass-gate transistor R-PG to the storage node (SN) positioned at a higher metal level. A source/drain contact 160G and a source/drain contact via 170G landing thereon electrically connect a common source region of the pull-down transistor PD-1 and the pull-down transistor PD-2 to the VSS line positioned at a higher metal level. A source/drain contact 160H and a source/drain contact via 170H landing thereon electrically connect a common source region of the pull-up transistor PU-1 and the pull-up transistor PU-2 to the VDD line positioned at a higher metal level. In the illustrated embodiment, the source/drain contacts 160A-160H each are elongated and have a longitudinal direction in the Y-axis, which is parallel to the extending directions of the gate structures 112-120.

The storage node SN includes the gate via 150E and the source/drain contact via 170F positioned on two opposing sides of the gate structure 116. As will be described in further detail below, a metal line at the M0 level extends along the X-axis to connect the gate via 150E and the source/drain contact via 170F. In other words, an M0 metal line hangs over the gate structure 116 and provides the function of cross coupling between the gate via 150E and the source/drain contact via 170F. Therefore, in the layout, the gate via 150E and the source/drain contact via 170F are positioned as being level along the Y-axis, such that a metal line extending along the X-axis may connect both. Similarly, the complementary storage node (storage node bar) SNB includes the gate via 150F and the source/drain contact via 170E positioned on two opposing sides of the gate structure 114. As will be described in further detail below, another metal line at the M0 level extends along the X-axis to across the gate structure 114 and connects the gate via 150F and the source/drain contact via 170E. In other words, another M0 metal line hangs over the gate structure 114 and provides the function of cross coupling between the gate via 150F and the source/drain contact via 170E. Therefore, in the layout, the gate via 150F and the source/drain contact via 170E are positioned as being level along the Y-axis, such that a metal line extending along the X-axis may connect both.

Reference is now made to FIG. 5, which illustrates a portion of the layout including the V0 level and M0 level of the memory device 1000. At the M0 level, the memory device 1000 includes a number of metal tracks arranged in parallel. Particularly, in the illustrated embodiment of the layout, the memory device 1000 includes six metal tracks arranged in order from first (M0 Track 1) to sixth (M0 Track 6) along the Y-axis. In the present disclosure, metal lines having longitudinal dimensions less than dimensions of the SRAM cell 100, such as dimensions along the X-axis that are less than the cell width S1 and dimensions along the Y-axis that are less than cell height S2, are referred to as local metal lines, and metal lines having longitudinal dimensions no less than dimensions of the SRAM cell 100, such as dimensions along the X-axis that are less than cell width S1 along the X-axis and dimensions along the Y-axis that are less than cell height S2 along the Y-axis, are referred to as global metal lines.

As depicted in FIG. 5, the first metal track “M0 Track 1” includes a global metal line 510, which is the VSS line, disposed on and electrically coupled to the source/drain contact via 170G. The VSS line is disposed on an upper edge of the boundary 190 of the SRAM cell 100 and may be shared with an adjacent SRAM cell.

The second metal track “M0 Track 2” includes a local metal line 520 as a landing pad for the write-port word line W_WL positioned at a higher metal level. In a top view, the local metal line 520 is fully within the boundary 190 of the SRAM cell 100. The local metal line 520 is disposed over and in direct contact with the gate via 150C and the gate via 150D.

The third metal track “M0 Track 3” includes three local metal lines 530A, 530B, and 530C. The local metal line 530A provides a landing pad for the write-port complimentary bit line W_BLB positioned at a higher metal level. In the top view, the local metal line 530A extends beyond a left edge of the boundary 190 of the SRAM cell 100 and may be shared with an adjacent SRAM cell. In the top view, the local metal line 530B is fully within the boundary 190 of the SRAM cell 100, which belongs to the storage node (SN) and provides cross-coupling between the gate via 150E and the source/drain contact via 170F. As described above, when viewed from top, the local metal line 530B crosses over the gate structure 116. The local metal line 530C provides a landing pad for the write-port bit line W_BL positioned at a higher metal level. In the top view, the local metal line 530C extends beyond a right edge of the boundary 190 of the SRAM cell 100 and may be shared with an adjacent SRAM cell.

The fourth metal track “M0 Track 4” includes one local metal line 540. In the top view, the local metal line 540 is fully within the boundary 190 of the SRAM cell 100 and belongs to the complementary storage node (SNB) and provides cross-coupling between the gate via 150F and the source/drain contact via 170E. As described above, when viewed from top, the local metal line 540 crosses over the gate structure 116. It is noted that, within the boundary 190, the “M0 Track 4” does not have other metal lines.

The fifth metal track “M0 Track 5” includes a global metal line 550, which is the read-port bit line RBL, electrically coupled to the source/drain contact via 170A. In the top view, the read-port bit line RBL may extend beyond the left edge and/or the right edge of the boundary 190 of the SRAM cell 100 and may be shared with an adjacent SRAM cell. That is, the length of the read-port bit line RBL is equal to or greater than the cell width along the X-axis. By placing the read-port bit line RBL at the M0 level and configuring the read-port bit line RBL as a global metal line, the speed of the memory device 1000 may be advantageously increased. In addition, forming this read-port bit line RBL at the M0 level also avoids the formation of a small landing pad(s) for the read-port bit line RBL, thereby alleviating overlay issues and lowering process risk.

The sixth metal track “M0 Track 6” includes a global metal line 560, which is the VDD line, electrically coupled to the source/drain contact via 170H. The VDD line is disposed directly over a lower edge of the boundary 190 of the SRAM cell 100 and may be shared with an adjacent SRAM cell.

In the depicted embodiment, the metal lines (e.g., the local metal lines 520, 530A-530C, 540 and global metal lines 510, 550, 560) at the M0 level have longitudinal dimensions along the X-axis. Local metal lines at the M0 level have longitudinal dimensions that are less than dimensions of the SRAM cell 100, such as dimensions along the X-axis that are less than cell width S1 and dimensions along the Y-direction that are less than cell height S2. As a comparison to the local metal lines, the VSS line (i.e., the metal line 510), read-port bit line (i.e., the metal line 550) and the VDD line (i.e., the metal line 560) have longitudinal dimensions along the X-axis that are equal to or greater than cell width of the SRAM cell 100. Each of the metal lines 520, 530A-530C, 540, and 550 has a same width along the Y-axis, which is less than the width of the VSS line and VDD line.

Reference is now made to FIG. 6, which illustrates a portion of the layout including the BV0 level, BM0 level, BV1 level, and BM1 level of the memory device 1000. As described above, the gate structure 118 of the read-port pass-gate transistor R-PG is electrically connected to the read-port word line R_WL. In the present embodiments, to increase the design flexibility of metal lines at the M0 level, increase speed of the memory device, and alleviate leakage and overlay issues caused by forming small landing pads over the device layer DL of the SRAM cell 100, instead of forming the read-port word line R_WL and its landing pad(s) over the device layer DL of the SRAM cell 100, the read-port word line R_WL in the present embodiments is positioned under the device layer DL of the SRAM cell 100. More specifically, at the BV0 level, a gate via 610 is formed directly under and in direct contact with the gate structure 118 of the read-port pass-gate transistor R-PG to electrically connect the gate structure 118 to the read-port word line R_WL positioned at a lower metal level. The gate via 610 may be referred to as a backside gate via 610 or a backside gate via BV0, and the gate vias 150C, 150D, 150E, and 150F may be referred to as frontside gate vias 150C, 150D, 150E, and 150F, respectively. The backside gate via 610 has a width Wx along the X-axis and a width Wy along the Y-axis. The landing area provided by the backside gate via 610 is equal to the product of Wx and Wy (i.e., Wx*Wy). The N-type fin 102 has a width D1 along the Y-axis, the P-type fin 104 has a width D2 along the Y-axis. In some embodiments, the width D1 is substantially equal to the width D2. In some embodiments, a ratio of the width Wx to a width Wg of the gate structure 118 along the X-axis is in a range between about 0.5 and 1.5. In some embodiments, a ratio of the width Wy to the width D2 is in a range between about 0.5 and 1.5.

Still referring to FIG. 6, at the BM0 level, the memory device 1000 includes a local metal line 620, which provides a landing pad of the read-port word line R_WL, disposed under and in direct contact with the backside gate via 610 and configured to electrically couple the backside gate via 610 to the read-port word line R_WL positioned at a lower metal level. In the present embodiments, the local metal line 620 extends lengthwise along the X-axis. In a top view, the local metal line 620 is fully within the boundary 190 of the SRAM cell 100. The local metal line 620 has a width D3 along the Y-axis and a length L3 along the X-axis. In some embodiments, to provide a reduced resistance, a ratio of the width D3 to the width D2 is in a range between about 1 and 3, and to provide a reduced capacitance associated with the read-port word line, a ratio of the length L3 to the width Wg (i.e., L3/Wg) is in a range between about 2 and 10. In embodiments represented by FIG. 6, when viewed from top, the local metal line 620 crosses over the gate structures 118, 116, and 114 and thus crosses over a central line 100c of the SRAM cell 100 along the Y-axis. The central line 100c divides the SRAM cell 100 into two portions having the same shape and area. In an embodiment, a distance between the central line 100c and the gate structure 114 equals a distance between the central line 100c and the gate structure 116. The local metal line 620 may be referred to as a backside local metal line 620 or metal line BM0, and the local metal lines formed over the device layer DL may be referred to as frontside local metal lines. The local metal line 620 crosses over the central line 100c of the SRAM cell 100 so as to provide a landing area for the read-port word line R_WL that is placed at the middle of the SRAM cell 100 when viewed from top.

At the BV1 level, a via 630 is formed under and in direct contact with the local metal line 620 to electrically connect the local metal line 620 to the read-port word line R_WL positioned at a lower metal level. The via 630 may be referred to as a backside via 630 or backside via BV1.

At the BM1 level, the memory device 1000 includes a global metal line 640, which is the read-port word line R_WL, disposed under and in direct contact with the via 630 and electrically coupled to the gate structure 118. The global metal line 640 may also be referred to as a backside metal line BM1. In the top view, the read-port word line R_WL may extend beyond the upper edge and/or the lower edge of the boundary of the SRAM cell 100 and may be shared with an adjacent SRAM cell. That is, the length of the read-port word line R_WL is equal to or greater than the cell height S2 along the Y-axis. In some embodiments, to provide satisfactory parasitic resistance and parasitic capacitance, a ratio of a width D4 of the global metal line 640 to the width Wg (i.e., D4/Wg) is in a range of about 2 and 10. In the present embodiments, when viewed from top, the read-port word line R_WL (i.e., the global metal line 640) is positioned at the middle of the boundary of the SRAM cell 100. That is, a central line of the read-port word line R_WL along the Y-axis is aligned with the central line 100c of the SRAM cell. The vias 610 and 630 and metal lines 620 and 640 will be described in further detail with reference to the cross-sectional views of the memory device 1000 depicted in FIGS. 9-10. Forming the read-port word line R_WL and associated landing pads (e.g., the local metal line 620) at the backside of the SRAM cell 100 would reduce the density of metal lines formed at the M0 level and thus increase design flexibility.

Reference is now made to FIG. 7, which illustrates a portion of the layout including the M0 level, V1 level, and M1 level of the memory device 1000. At the V1 level, the memory device 1000 includes a number of vias formed over and in direct contact with the M0 level. For example, the V1 level of the memory device 1000 includes a via 710A formed over and in direct contact with the local metal line 530A to electrically couple the local metal line 530A to the complementary write-port bit line W_BLB positioned at a higher interconnect layer. The V1 level of the memory device 1000 also includes a via 710B formed over and in direct contact with the local metal line 520 to electrically couple the local metal line 520 to the write-port word line W_WL positioned at a higher metal level. The V1 level of the memory device 1000 also includes a via 710C formed over and in direct contact with the global metal line 510 and electrically connecting the global metal line 510 to a metal line positioned at a higher metal level. The V1 level of the memory device 1000 also includes a via 710E formed over and in direct contact with the local metal line 530C to electrically connect the local metal line 530C to the write-port bit line W_BL positioned at a higher metal level.

At the M1 level, the memory device 1000 includes a number of metal lines formed over the V1 level. For example, the M1 level of the memory device 1000 includes a local metal line 720A formed over and in direct contact with the via 710A to electrically couple the via 710A to the complementary write-port bit line W_BLB positioned at a higher metal level. The local metal line 720A may also be referred to as a landing pad for the complementary write-port bit line W_BLB. The local metal line 720A may extend beyond a left edge of the boundary 190 of the SRAM cell 100 and may be shared with an adjacent SRAM cell.

The M1 level of the memory device 1000 also includes a global metal line 720B, which is the write-port word line W_WL, disposed on and electrically coupled to the via 710B. The write-port word line W_WL may extend beyond the upper edge and/or the lower edge of the boundary 190 of the SRAM cell 100 and may be shared between adjacent SRAM cells. The M1 level of the memory device 1000 also includes a global metal line formed over and in direct contact with the via 710C. The M1 level of the memory device 1000 also includes a global metal line 720D disposed adjacent to the global metal line 720C. The M1 level of the memory device 1000 also includes a local metal line 720E formed over and in direct contact with the via 710E to electrically couple the via 710E to the write-port bit line W_BL positioned at a higher metal level. The local metal line 720E may also be referred to as a landing pad for the write-port bit line W_BL. The local metal line 720E may extend beyond a right edge of the boundary 190 of the SRAM cell 100 and may be shared with an adjacent SRAM cell. As depicted in FIG. 7, in the top view, all the metal lines (including the global metal lines 720B, 720C, 720D and the local metal lines 720A, 720E) at the M1 level extend lengthwise along the Y-axis.

Reference is now made to FIG. 8, which illustrates a portion of the layout including the M1 level, V2 level, and M2 level of the memory device 1000. At the V2 level, the memory device 1000 includes a number of vias formed over the M1 level. For example, the V2 level of the memory device 1000 includes a via 810A formed over and in direct contact with the local metal line 720A to electrically couple the local metal line 720A to the complementary write-port bit line W_BLB positioned at a higher metal level. The V2 level of the memory device 1000 also includes a via 810B formed over and in direct contact with the local metal line 720E to electrically couple the local metal line 720E to the write-port bit line W_BL positioned at a higher metal level.

At the M2 level, the memory device 1000 includes a number of metal lines formed over the V2 level. In the present embodiments, the memory device 1000 includes a global metal line 820A, which is the complementary write-port bit line W_BLB, formed over and in direct contact with the via 810A. The memory device 1000 also includes a global metal line 820B, which is the write-port bit line W_BL, formed over and in direct contact with the via 810B. The write-port bit line W_BL and the complementary write-port bit line W_BLB both extend lengthwise along the X-axis, may extend beyond the left edge and/or the right edge of the boundary 190 of the SRAM cell 100, and may be shared with an adjacent SRAM cell.

Compared with embodiments in which the read-port word line RWL is formed over the device layer DL of the SRAM cell, forming the read-port word line RWL under the device layer DL of the SRAM cell may relax the design flexibility of the metal lines formed at the M0 level. In addition, forming the read-port bit line RBL at the M0 level may also relax the metal lines at other metal levels (e.g., the M2 level). Thus, the complementary write-port bit line W_BLB and the write-port bit line W_BL formed at the M2 level in the present embodiments may have increased widths, leading to a reduced parasitic resistance and increased write speed.

FIG. 9 illustrates a cross-sectional view of the memory device 1000 taken along line A-A shown in FIGS. 4 and 6, in accordance with some embodiments of the present disclosure. FIG. 10 illustrates a cross-sectional view of the memory device 1000 taken along line B-B shown in FIG. 9, in accordance with some embodiments of the present disclosure. A cross-sectional view of the memory device 1000 cut through the N-type fin 102 and the gate structures 112, 114, 116, and 120 is similar to the cross-sectional view of the memory device 1000 shown in FIG. 9 and repeated description is omitted for reason of simplicity.

As depicted in FIGS. 9-10, the SRAM cell 100 (as a portion of the memory device 1000) is formed over a substrate (or a wafer) 902. In an embodiment, the substrate 902 includes silicon. The substrate 902 includes a number of p-wells (not shown) and n-wells (not shown) formed therein (and/or thereover) according to various design requirements of the memory device 1000. The n-well is configured to provide at least one p-type field-effect transistor (PFET), such as a pull-up transistor, and the p-well is configured to provide at least one n-type field-effect transistor (NFET), such as a pull-down transistor or a pass-gate transistor. In some embodiments, the substrate 902 may include additional doped regions configured to provide one or more transistors according to design requirements of the memory device 1000.

In the present embodiments represented by FIGS. 9-10, the transistors (e.g., the pull-up transistors PU-1 and PU-2, the pull-down transistors PD-1 and PD-2, the pass gate transistors PG-1. PG-2, and R-PG) of the SRAM cell 100 include GAA transistors. The P-type fin 104 includes a stack of semiconductor layers 908 and a portion of the substrate 902 thereunder; similarly, and the N-type fin 102 includes a stack of semiconductor layers and a portion of the substrate 902 thereunder. In the depicted embodiments, the semiconductor layers 908 are stacked vertically along the Z-axis. Each stack of the semiconductor layers 908 of the P-type fin 104 interposes P-type source/drain (S/D) features 910P, and each stack of the semiconductor layers of the N-type fin 102 interposes N-type source/drain (S/D) features (not shown). The semiconductor layers 908 may include Si, Ge, SiC, SiGe, GeSn, SiGeSn, SiGeCSn, other suitable semiconductor materials, or combinations thereof. In the present embodiments, each of the semiconductor layers 908 includes a nanosheet, a nanowire (e.g., a nanowire having a hexagonal cross-section), a nanorod (e.g., a nanorod having a square or round cross-section), or other suitable configurations. In some embodiments, the N-type fin 102 and the P-type fin 104 each include two to ten channel layers 908, respectively. For example, the N-type fin 102 and the P-type fin 104 may each include three channel layers 908. Of course, the present disclosure is not limited to such configurations and the number of semiconductor layers may be tuned according to design requirements for the memory device 1000. Source/drain feature(s) may refer to a source or a drain, individually or collectively dependent upon the context. Exemplary N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Exemplary P-type source/drain features 910P may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, the N-type source/drain features and/or the P-type source/drain features 910P each may be a multi-layer structure that includes an undoped semiconductor layer, a lightly doped semiconductor layer over the undoped semiconductor layer, and a heavily doped semiconductor layer over the lightly doped semiconductor layer.

In the present embodiments, each gate structure (including the gate structures 112, 114, 116, 118, 120) includes at least a high-k gate dielectric layer (e.g., the gate dielectric layer 76 shown in FIG. 3) and a metal gate electrode (e.g., the gate electrode 74 shown in FIG. 3). In the present embodiments, portions of the high-k gate dielectric layer wrap around each channel layer, such that each gate structure engages the plurality of channel layers (e.g., channel layers 908) in each GAA transistor. The high-k gate dielectric layer may include silicon oxynitride, aluminum silicon oxide, a high-k dielectric material such as hafnium oxide, zirconium oxide, lanthanum oxide, titanium oxide, yttrium oxide, strontium titanate, other suitable dielectric materials, or combinations thereof. Though not depicted, each metal gate electrode may further include a bulk conductive layer disposed over at least one work function metal layer. The bulk conductive layer may include Cu, W, Ru, Co, Al, Ti, Ta, other suitable metals, or combinations thereof. In some examples, each gate structure may include one or more work function metal layer of the same conductivity type or of different conductivity types. Examples of the work function metal layers may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable work function materials, or combinations thereof. Various work function metal layers may be first deposited and then patterned to satisfy different requirements of threshold voltage in different GAA FETs. Additional material layers may also be included in each gate structure, such as an interfacial layer, a barrier layer, a capping layer, other suitable materials layers, or combinations thereof. Various layers of the gate structures may be deposited by any suitable method, such as chemical oxidation, thermal oxidation, atomic layer deposition (ALD), chemical vapor deposition (CVD), physical vapor deposition (PVD), plating, other suitable methods, or combinations thereof. The SRAM cell 100 may further include top spacers 912a and 912b and inner spacers 912c disposed on sidewalls of the gate structures, where the top spacers 912a and 912b are disposed over the channel layers 908 and the inner spacers 912c are disposed in the space between two vertically stacked channel layers 908. As depicted in FIG. 9, the 7T SRAM cell 100 also includes the dielectric feature 110. The dielectric feature 110 may be formed in a continuous-poly-on-diffusion-edge (CPODE) process. In a CPODE process, at least a portion of a polysilicon gate and the channel region thereunder are replaced by a dielectric feature, and a remaining portion of the polysilicon gate may be replaced by a functional gate structure. For purposes of this disclosure, a “diffusion edge” may be equivalently referred to as an active edge, where for example an active edge abuts adjacent active regions. The dielectric feature 110 is also referred to as a CPODE feature 110. The CPODE feature 110 extends into the substrate 902.

Still referring to FIGS. 9-10, the memory device 1000 includes a contact etch stop layer (CESL) 914 and a first interlayer dielectric (ILD) layer 916 deposited over the P-type source/drain features 910P. The CESL 914 may include silicon nitride, silicon oxynitride, and/or other suitable materials and may be formed by ALD, plasma-enhanced chemical vapor deposition (PECVD) process and/or other suitable deposition or oxidation processes. The first ILD layer 916 may be deposited by a PECVD process or other suitable deposition technique after the deposition of the CESL 914. The first ILD layer 916 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The memory device 1000 also includes an etch stop layer 918 and a second interlayer dielectric (ILD) layer 920 deposited over the first ILD layer 916 and the gate structures (including the gate structures 112, 114, 116, 118, 120). The formations and compositions of the etch stop layer 918 and the second ILD layer 920 are similar to those of the CESL 914 and the first ILD layer 916, respectively.

Still referring to FIGS. 9 and 10, the memory device 1000 includes the source/drain contacts (including the source/drain contacts 160E, 160H, 160F, 160A) extending through the etch stop layer 918, the first and second ILD layers 916 and 920, and the CESL 914. Each of the frontside source/drain contacts (including the source/drain contacts 160E, 160H, 160F, 160A) are formed over the respective source/drain features and electrically coupled to the respective source/drain feature 910P via a silicide layer 922. The source/drain contacts (including the source/drain contacts 160E, 160H, 160F, 160A) may include any suitable conductive material, such as Cu, W, Ru, Co, Al, Ti, Ta, other suitable metals, or combinations thereof and may further include a barrier layer comprising any suitable material, such as Ti, Ta, TiN, TaN, other suitable materials, or combinations thereof. In some embodiments, the silicide layer 922 may include nickel silicide, titanium silicide, cobalt silicide, other suitable silicides, or combinations thereof.

To increase the design flexibility of metal lines at the M0 level and alleviate leakage and overlay issues, the read-port word line R_WL of the memory device 1000 is disposed under the SRAM cell 100. As depicted in FIGS. 9-10, the memory device 1000 includes the gate via 610 disposed under and in direct contact with the gate structure 118 of the read-port pass-gate transistor R-PG of the SRAM cell 100. The gate via 610 is spaced apart from the substrate 902 by a dielectric liner 915. In some embodiments, the dielectric liner 915 may include silicon nitride or other suitable materials. In embodiments represented by FIG. 10, the backside gate via 610 is in direct contact with both the gate structure 118 and the channel region of the P-type fin 104 that is disposed directly under the gate structure 118.

The memory device 1000 includes the backside local metal line 620, which is the landing pad of the read-port word line R_WL, disposed under the substrate 902 and in direct contact with the backside gate via 610. The backside local metal line 620 is embedded in a dielectric layer 930 and spaced apart from the substrate 902 by an etch stop layer 928. The dielectric layer 930 and the etch stop layer 928 are similar to the second ILD layer 920 and etch stop layer 918, respectively.

The memory device 1000 includes an etch stop layer 938 and a dielectric layer 940 disposed under the backside local metal line 620. The dielectric layer 940 and the etch stop layer 938 are similar to the second ILD layer 920 and etch stop layer 918, respectively. The backside via 630 extends through the dielectric layer 940 and the etch stop layer 938, and electrically connects to and in direct contact with the backside local metal line 620.

The memory device 1000 also includes an etch stop layer 948 and a dielectric layer 950 disposed under the backside via 630. The dielectric layer 950 and the etch stop layer 948 are similar to the second ILD layer 920 and etch stop layer 918, respectively. The backside metal line 640, which is the read-port word line R_WL, extends through the dielectric layer 950 and the etch stop layer 948, and electrically connects to and in direct contact with the backside via 630. Since the backside local metal line 620 and the read-port word line R_WL are formed under the SRAM cell 100 instead of being formed over the SRAM cell 100, the dimensions of the backside local metal line 620 and the read-port word line R_WL may be flexibly adjusted to achieve satisfactory performance. That is, the parasitic capacitance and parasitic resistance of the memory device 1000 may be optimized by adjusting the dimensions (e.g., width, thickness) of the backside local metal line 620 and the read-port word line R_WL.

FIG. 11 illustrates a first alternative layout of the memory device 1000, in portion or entirety, according to various aspects of the present disclosure. In the above embodiments described with reference to FIG. 6 and FIG. 9, the backside gate via 610 is disposed directly under the channel region of the P-type fin 104 and in direct contact with the gate structure 118. In the alternative embodiment represented by FIG. 11, the backside gate via 610 is disposed directly under and in direct contact with the gate structure 118 and is not vertically overlapped with the P-type fin 104. That is, in a cross-sectional view, as indicated by the dashed line 1100 shown in FIG. 10, the backside gate via 610 in this alternative embodiment may extend through the STI feature 904 to contact the gate structure 118 and be disposed between two adjacent fins (e.g., the N-type fin 102 and P-type fin 104). In some other embodiments, the backside gate via 610 may be vertically overlapped with both the STI feature 904 and the channel region of the P-type fin 104. That is, in a cross-sectional view, the backside gate via 610 may extend through both the channel region of the P-type fin 104 and the STI feature 904 to direct contact the gate structure 118, as indicated by the dashed line 1100′ shown in FIG. 10.

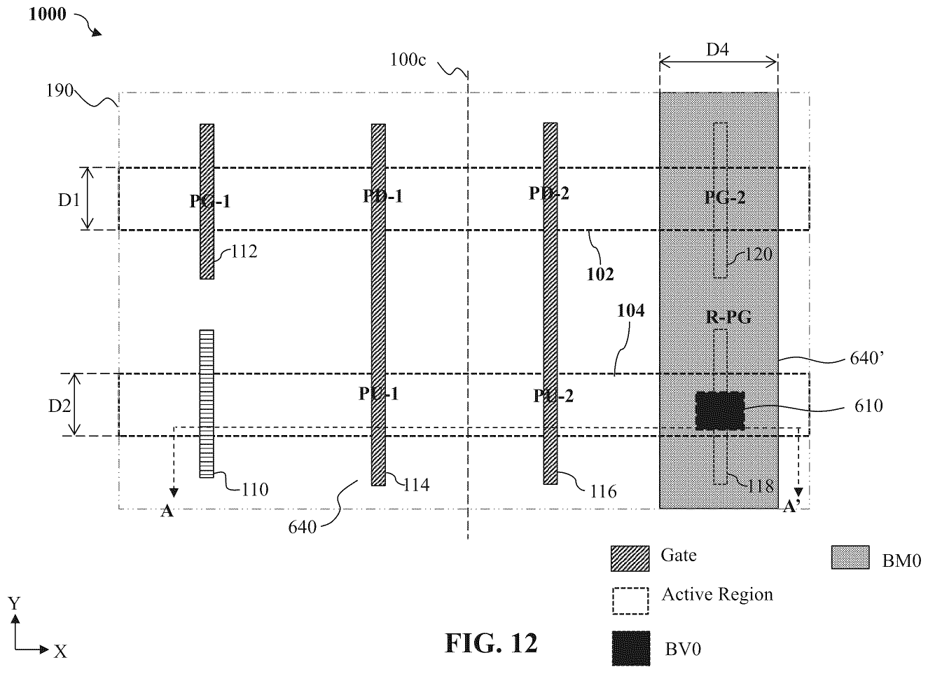

FIG. 12 illustrates a second alternative layout of the memory device 2000, in portion or entirety, according to various aspects of the present disclosure. In the above embodiments described with reference to FIG. 6, the global metal line 640 (i.e., the read-port word line RWL) is positioned at the BM1 level and is electrically coupled to the gate structure 118 of the read-port pass gate transistor R-PG by way of the backside gate via 610 formed at the BV0 level, the local metal line 620 formed at the BM0 level, and the backside via 630 formed at the BV1 level. In this alternative embodiment, a global metal line 640′, which is the read-port word line RWL, is positioned at the BM0 level, extends lengthwise along the Y-axis, and is electrically coupled to the gate structure 118 of the read-port pass gate transistor R-PG by way of the backside gate via 610 formed at the BM0 level. In this alternative embodiments, there is an offset between the central line of the global metal line 640′ (i.e., the read-port word line RWL) and the central line 100c of the SRAM cell 100.

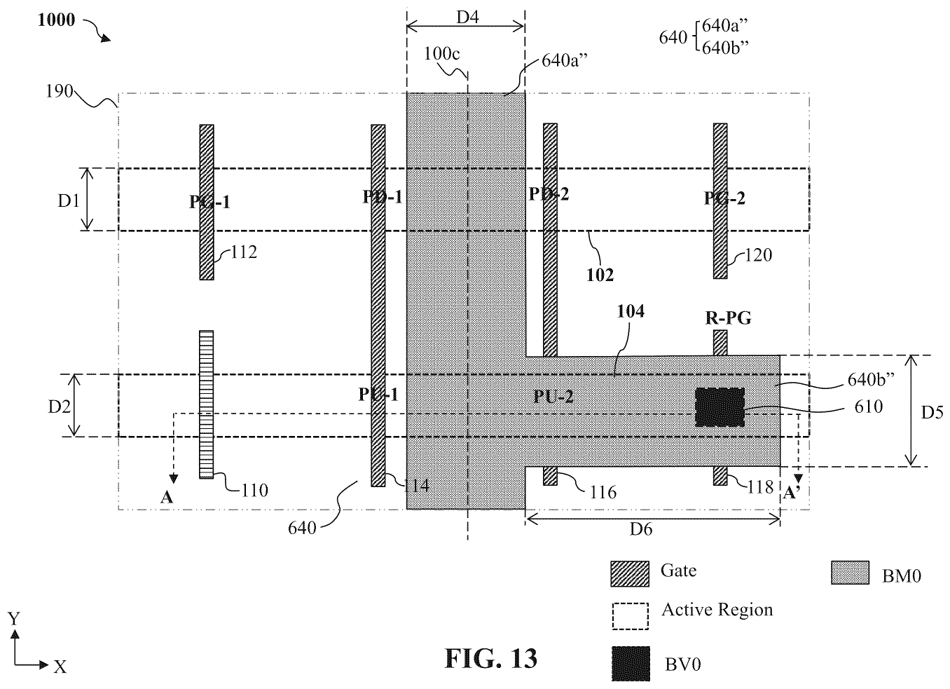

FIG. 13 illustrates a third alternative layout of the memory device 1000, in portion or entirety, according to various aspects of the present disclosure. The third alternative layout of the memory device 2000 depicted in FIG. 13 is similar to the second alternative layout of the memory device 2000 depicted in FIG. 12. That is, in this third alternative embodiment, a global metal line 640″, which is the read-port word line RWL, is positioned at the BM0 level and is electrically coupled to the gate structure 118 of the read-port pass gate transistor R-PG by way of the backside gate via 610 formed at the BM0 level. One difference between these two layouts depicted in FIG. 12 and FIG. 13 includes the shape of the read-port word line RWL. More specifically, in this third alternative embodiment, the global metal line 640″ includes a first portion 640a″ extending lengthwise along the Y-axis, and a central line of the first portion 640a″ is aligned with the central line 100c of the SRAM cell when viewed from top. In some embodiments, the length of the first portion 640a″ is no less than the cell height of the SRAM cell 100 along the Y-axis. The global metal line 640″ also includes a second portion 640b″ protruding from the first portion 640a″ and extending lengthwise along the X-axis. The backside gate via 610 is disposed directly over and in direct contact with the second portion 640b″. The second portion 640b″ has a width D5 along the Y-axis and a length D6 along the X-axis. In some embodiments, a ratio of the width D5 to the width D2 (i.e., D5/D2) is in a range between about 0.5 and 5, and a ratio of the width D6 to the width Wg (i.e., D6/Wg) is in a range between about 1 and 5. As described above with reference to FIGS. 10-11, the backside gate via 610 may be in direct contact with the P-type fin 104, the STI feature 904, or both. Forming this global metal line 640″ enables the first portion 640a″ to be disposed under the center of the SRAM cell 100, thereby reducing a parasitic capacitance.

FIG. 14 illustrates a layout of various layers of another memory device 2000, in portion or entirety, according to various aspects of the present disclosure. As depicted in FIG. 14, the memory device 2000 includes two SRAM cells. For example, the memory device 2000 includes the SRAM cell 100A and the SRAM cell 100C. The layout of the SRAM cell 100A is substantially the same as the layout of the SRAM cell 100 described with reference to FIG. 4, and the layout of the SRAM cell 100C is a mirror image of a layout of the SRAM cell 100A with respect to the X-axis. The SRAM cell 100C includes pull-up transistors PU-1′, PU-2′, pull-down transistors PD-1′, PD-2′, pass-gate transistors PG-1′, PG-2′, and read-port pass-gate transistor R-PG′ formed by gate structures 112′, 114′, 116′, 118′, 120′ and N-type fin 102′ and P-type fin 104′, and has a cell boundary 190′, like reference numerals (e.g., 112′ and 112) denote like features unless otherwise excepted, and repeated description is omitted for reason of simplicity.

The memory device 2000 includes the backside gate via 610 disposed under the gate structure 118 of the SRAM cell 100A, the local metal line 620 disposed under and in direct contact with the backside gate via 610, and the backside via 630 disposed under and in direct contact with the local metal line 620, as described above with reference to FIG. 6. Similarly, as depicted in FIG. 14, the memory device 2000 also includes a backside gate via 610′ disposed under the gate structure 118′ of the SRAM cell 100C, a local metal line 620′ disposed under and in direct contact with the backside gate via 610′, and a backside via 630′ disposed under and in direct contact with the local metal line 620′. The backside gate via 610′, the local metal line 620′, and the backside via 630′ are substantially the same as the backside gate via 610, the local metal line 620, and the backside via 630, respectively. The memory device 2000 also includes the global metal line 640, which is the read-port word line RWL, disposed under the SRAM cell 100A and the SRAM cell 100C, and extends lengthwise along the Y-axis to cross the cell boundary 190 and the cell boundary 190′. In the present embodiment, the read-port word line RWL is in direct contact with both the backside via 630′ and the backside via 630 to electrically couple to both the gate structure 118 of the read-port pass gate transistor R-PG of the SRAM cell 100A and the gate structure 118′ of the read-port pass gate transistor R-PG′ of the SRAM cell 100C.

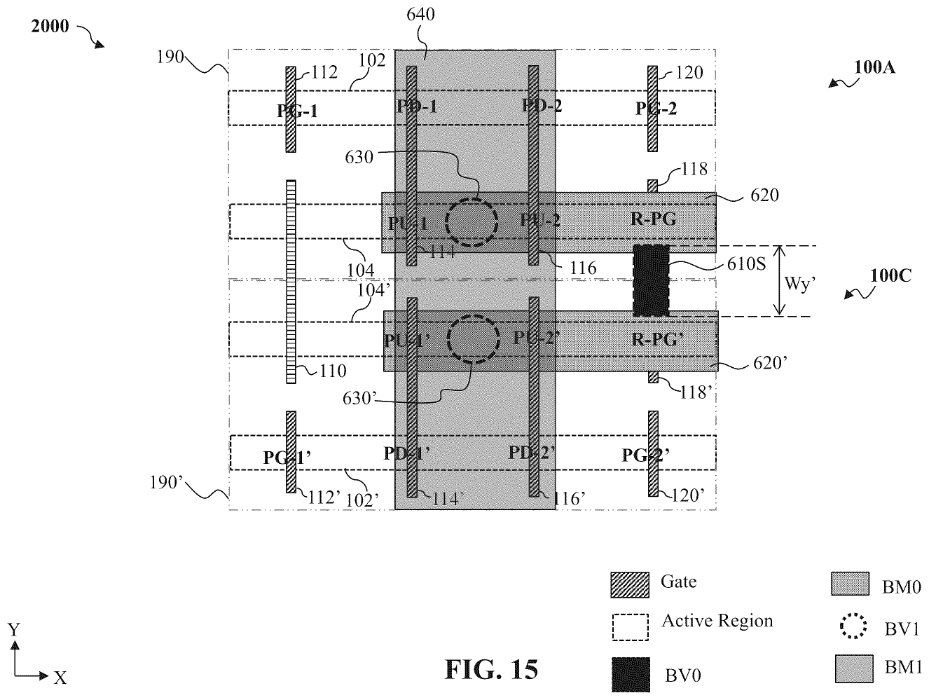

FIG. 15 illustrates a first alternative layout of various layers of the memory device 2000 in FIG. 14, in portion or entirety, according to various aspects of the present disclosure. The first alternative layout depicted in FIG. 15 is similar to that of FIG. 14. One difference between these two layouts include that, as depicted in FIG. 15, the memory device 2000 includes a backside gate via 610S disposed under and in direct contact with both the gate structure 118 of the read-port pass gate transistor R-PG of the SRAM cell 100A and the gate structure 118′ of the read-port pass gate transistor R-PG′ of the SRAM cell 100C. That is, the backside gate via 610S is shared by the two SRAM cells 100A and 100C. The backside gate via 610S has a first portion vertically overlapped with the local metal line 620, a second portion vertically overlapped with the local metal line 620′, and a third portion not vertically overlapped with the local metal line 620 or the local metal line 620′. In some embodiments, a ratio of a length Wy′ of the backside gate via 610S to the width D2 is in a range between about 0.5 and about 10.

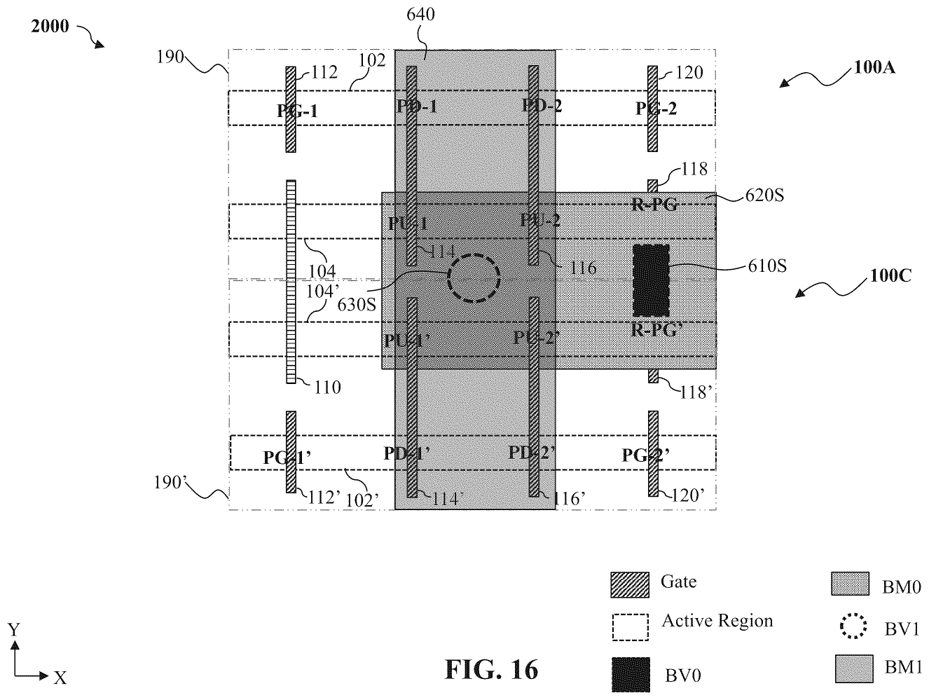

FIG. 16 illustrates a second alternative layout of various layers of the memory device 2000 in FIG. 14, in portion or entirety, according to various aspects of the present disclosure. The second alternative layout depicted in FIG. 16 is similar to that of FIG. 15. One difference between these two layouts include that, as depicted in FIG. 16, instead of having two local metal lines (e.g., the local metal lines 620 and 620′), the memory device 2000 includes a local metal line 620S disposed under the backside gate via 610S. The local metal line 620S is vertically overlapped with both the SRAM cell 100A and the SRAM cell 100C. Another difference between these two layouts include that, as depicted in FIG. 16, instead of having two backside vias (e.g., the backside vias 630 and 630′), the memory device 2000 includes a backside via 630S disposed under the local metal line 620S and is vertically overlapped with both the SRAM cell 100A and the SRAM cell 100C. That is, the global metal line 640 (i.e., the read-port word line RWL) is electrically coupled to the gate structure 118 of the SRAM cell 100A and the gate structure 118′ of the SRAM cell 100C by a common backside via (i.e., the backside via 630S) at the BV1 level, a common local metal line (i.e., the local metal line 620S) at the BM0 level, and a common backside gate via (i.e., the backside gate via 610S) at the BV0 level.

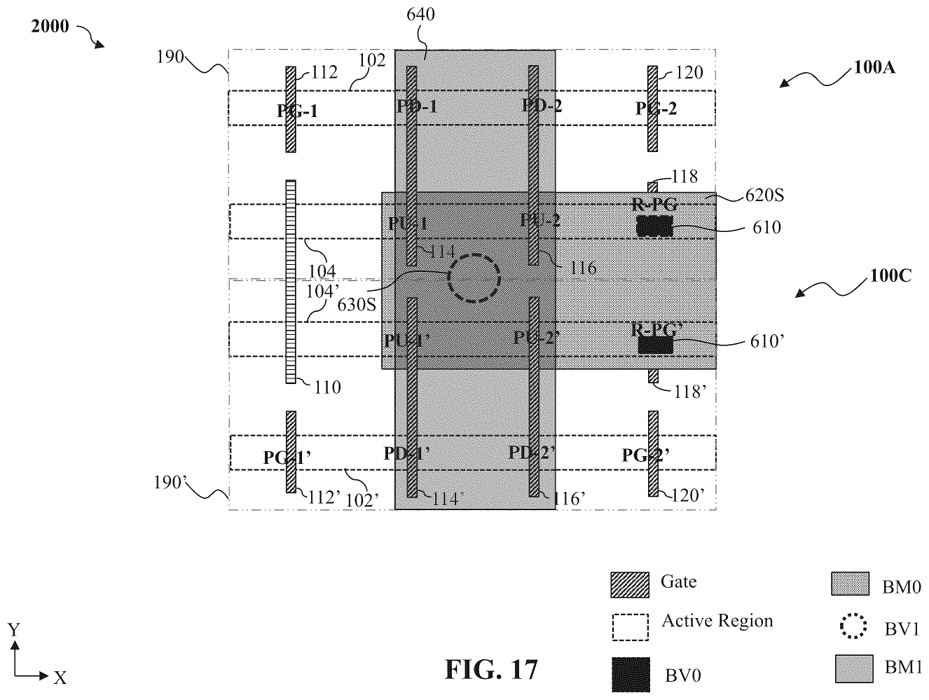

FIG. 17 illustrates a third alternative layout of various layers of the memory device 2000 in FIG. 14, in portion or entirety, according to various aspects of the present disclosure. The third alternative layout depicted in FIG. 17 is similar to that of FIG. 16. One difference between these two layouts include that, as depicted in FIG. 17, instead of having one common backside gate via 610S, the memory device 2000 includes the backside gate vias 610 and 610′ described with reference to FIG. 14. That is, the global metal line 640 (i.e., the read-port word line RWL) is electrically coupled to the gate structure 118 of the SRAM cell 100A and the gate structure 118′ of the SRAM cell 100C by a common backside via (i.e., the backside via 630S at the BV1 level), a common local metal line (i.e., the local metal line 620S) at the BM0 level, and two corresponding backside gate vias (i.e., the backside gate vias 610 and 610′) at the BV0 level.

In the above embodiments described with reference to FIGS. 2-17, structures of memory devices 1000/2000 including 7T SRAM cells are described. The inventive concepts (e.g., forming the read-port word line R_WL at the backside of the SRAM cell) are also applicable for memory devices including a two-port SRAM cell that has eight transistors (8T). FIG. 18 is a circuit diagram of an 8T SRAM cell 100′ that can be implemented in the IC chip of FIG. 1, according to various aspects of the present disclosure. The 8T SRAM cell 100′ is similar to the 7T SRAM cell 100, and one difference between the two SRAM cells is that the 8T SRAM cell 100′ includes another read-port pass gate transistor R-PG2. The read-port word line RWL of a memory device including the 8T SRAM cell 100′ may be formed under the device layer of the 8T SRAM cell 100′.

Although not intended to be limiting, one or more embodiments of the present disclosure provide many benefits to a memory device and the formation thereof. It is understood, however, that other embodiments may offer additional advantages, and not all advantages are necessarily disclosed herein, and that no particular advantage is required for all embodiments. For example, the present disclosure provides a memory device including a SRAM cell and a read-port word line disposed under the SRAM cell. Forming the read-port word line disposed under the SRAM cell relaxes the design flexibility of frontside conductive features (e.g., metal lines) formed over the SRAM cell and alleviates leakage and short issue associated with the frontside conductive features. In some embodiments, forming the read-port word line disposed under the SRAM cell allows reduction of the parasitic capacitance and parasitic resistance of the memory device, thereby improving the overall performance.

The present disclosure provides for many different embodiments. Semiconductor structures and methods of fabrication thereof are disclosed herein. In one exemplary aspect, the present disclosure is directed to a semiconductor structure. The semiconductor structure includes a two-port static random access memory (SRAM) cell comprising a write port portion and a read port portion electrically coupled to the write port portion and comprising a transistor having a gate structure. The semiconductor structure also includes a first plurality of metal lines comprising a write bit line and a complementary write bit line, wherein the first plurality of metal lines are positioned at a first interconnect layer disposed over the gate structure; and a read word line positioned at a second interconnect layer and electrically coupled to the gate structure, wherein the second interconnect layer is disposed under the gate structure.

In some embodiments, the semiconductor structure may also include a first via disposed under and in direct contact with the gate structure, a landing pad disposed directly under and in direct contact with the first via, and a second via disposed directly under and in direct contact with the landing pad. The second interconnect layer is disposed under and in direct contact with the second via. In some embodiments, the first via may be vertically overlapped with a channel region of the transistor. In some embodiments, the first via may be not vertically overlapped with a channel region of the transistor. In some embodiments, the landing pad extends lengthwise along a first direction, the gate structure extends lengthwise along a second direction substantially perpendicular to the first direction. In some embodiments, the transistor may also include a first source/drain feature electrically coupled to the write port portion and a second source/drain feature electrically coupled to a read bit line, and the read bit line may be positioned at a third interconnect layer disposed over the gate structure. In some embodiments, the semiconductor structure may also include a silicide layer disposed over and in direct contact with the second source/drain feature, and a source/drain contact disposed over and in direct contact with the silicide layer, where the third interconnect layer may be disposed over and in direct contact with the source/drain contact. In some embodiments, the transistor may also include a vertical stack of nanostructures, and the gate structure may include a first portion over the vertical stack of nanostructures and a second portion wrapping around each nanostructure of the vertical stack of nanostructures. In some embodiments, the gate structure and the read word line extend lengthwise along a same direction.

In another exemplary aspect, the present disclosure is directed to a semiconductor structure. The semiconductor structure includes a memory cell connected to a write word line and a read word line, a first interconnect structure disposed over the memory cell and comprising the write word line, and a second interconnect structure disposed under the memory cell and comprising the read word line.

In some embodiments, the memory cell may include a first active region and a second active region extending lengthwise along a first direction, and first and second gate structures extending lengthwise in a second direction perpendicular to the first direction, wherein the first gate structure engages the first active region in forming an N-type transistor, and the first gate structure may be electrically coupled to the write word line, and wherein the second gate structure engages the second active region in forming a P-type transistor, and the second gate structure may be electrically coupled to the read word line. In some embodiments, the P-type transistor may also include a first source/drain feature electrically coupled to a read bit line and a second source/drain feature electrically coupled to a source/drain feature of the N-type transistor, and wherein the first interconnect structure may include a source/drain contact disposed over the first source/drain feature, and a read bit line disposed over and in direct contact with the source/drain contact. In some embodiments, the second interconnect structure may include a first via disposed under and in direct contact with the second gate structure, a landing pad disposed directly under and in direct contact with the first via, a second via disposed directly under and in direct contact with the landing pad, and the read word line disposed directly under and in direct contact with the second via. In some embodiments, the first via may be disposed directly under a channel region of the P-type transistor. In some embodiments, the memory cell may also include an isolation feature configured to isolate the first active region from the second active region, and the first via extends through the isolation feature to direct contact the second gate structure. In some embodiments, the memory cell may include a seven-transistor static random access memory (SRAM) cell.

In yet another exemplary aspect, the present disclosure is directed to a semiconductor structure. The semiconductor structure includes a first memory cell comprising a write port portion, and a read port portion comprising a transistor having a first source/drain feature and a second source/drain feature coupled to a channel region, and a gate structure engaging the channel region. The semiconductor structure also includes a backside via disposed directly under and in direct contact with the gate structure, and a first interconnect layer disposed under and electrically coupled to the backside via, wherein a read word line may be positioned at the first interconnect layer.

In some embodiments, the first memory cell may be connected to a first power line for receiving a first power supply voltage, and a second power line for receiving a second power supply voltage, wherein the first power line and the second power line are positioned at a second interconnect layer disposed over the gate structure. In some embodiments, one of the first and second source/drain features may be electrically coupled to a read bit line, and the read bit line may be positioned at the second interconnect layer. In some embodiments, the semiconductor structure may also include a second memory cell, wherein the backside via may be further in direct contact with a gate structure of a transistor in a read port portion of the second memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a two-port static random access memory (SRAM) cell comprising:
a write port portion; and
a read port portion electrically coupled to the write port portion and comprising a transistor having a gate structure;
a first plurality of metal lines comprising a write bit line and a complementary write bit line, wherein the first plurality of metal lines are positioned at a first interconnect layer disposed over the gate structure; and
a read word line positioned at a second interconnect layer and electrically coupled to the gate structure, wherein the second interconnect layer is disposed under the gate structure.

2. The semiconductor structure of claim 1, further comprising:
a first via disposed under and in direct contact with the gate structure;
a landing pad disposed directly under and in direct contact with the first via; and
a second via disposed directly under and in direct contact with the landing pad,
wherein the second interconnect layer is disposed under and in direct contact with the second via.

3. The semiconductor structure of claim 2, wherein the first via is vertically overlapped with a channel region of the transistor.

4. The semiconductor structure of claim 2, wherein the first via is not vertically overlapped with a channel region of the transistor.

5. The semiconductor structure of claim 2, wherein the landing pad extends lengthwise along a first direction, the gate structure extends lengthwise along a second direction substantially perpendicular to the first direction.

6. The semiconductor structure of claim 2, wherein the transistor further comprises a first source/drain feature electrically coupled to the write port portion and a second source/drain feature electrically coupled to a read bit line, and the read bit line is positioned at a third interconnect layer disposed over the gate structure.

7. The semiconductor structure of claim 6, further comprising:
a silicide layer disposed over and in direct contact with the second source/drain feature; and
a source/drain contact disposed over and in direct contact with the silicide layer,
wherein the third interconnect layer is disposed over and in direct contact with the source/drain contact.

8. The semiconductor structure of claim 1, wherein the transistor further comprises a vertical stack of nanostructures, and the gate structure comprises a first portion over the vertical stack of nanostructures and a second portion wrapping around each nanostructure of the vertical stack of nanostructures.

9. The semiconductor structure of claim 1, wherein the gate structure and the read word line extend lengthwise along a same direction.

10. A semiconductor structure, comprising:
a memory cell connected to a write word line and a read word line;
a first interconnect structure disposed over the memory cell and comprising the write word line; and
a second interconnect structure disposed under the memory cell and comprising the read word line.

11. The semiconductor structure of claim 10, wherein the memory cell comprises:
a first active region and a second active region extending lengthwise along a first direction; and
first and second gate structures extending lengthwise in a second direction perpendicular to the first direction,
wherein the first gate structure engages the first active region in forming an N-type transistor, and the first gate structure is electrically coupled to the write word line, and
wherein the second gate structure engages the second active region in forming a P-type transistor, and the second gate structure is electrically coupled to the read word line.

12. The semiconductor structure of claim 11,
wherein the P-type transistor further comprises a first source/drain feature electrically coupled to a read bit line and a second source/drain feature electrically coupled to a source/drain feature of the N-type transistor, and
wherein the first interconnect structure comprises:
a source/drain contact disposed over the first source/drain feature; and
a read bit line disposed over and in direct contact with the source/drain contact.

13. The semiconductor structure of claim 11, wherein the second interconnect structure comprises:
a first via disposed under and in direct contact with the second gate structure;
a landing pad disposed directly under and in direct contact with the first via;
a second via disposed directly under and in direct contact with the landing pad, and
the read word line disposed directly under and in direct contact with the second via.

14. The semiconductor structure of claim 13, wherein the first via is disposed directly under a channel region of the P-type transistor.

15. The semiconductor structure of claim 13, wherein the memory cell further comprises an isolation feature configured to isolate the first active region from the second active region, and the first via extends through the isolation feature to direct contact the second gate structure.

16. The semiconductor structure of claim 11,
wherein the memory cell comprises a seven-transistor static random access memory (SRAM) cell.

17. A semiconductor structure, comprising:
a first memory cell comprising:
a write port portion; and
a read port portion comprising a transistor having a first source/drain feature and a second source/drain feature coupled to a channel region, and a gate structure engaging the channel region,
a backside via disposed directly under and in direct contact with the gate structure; and
a first interconnect layer disposed under and electrically coupled to the backside via, wherein a read word line is positioned at the first interconnect layer.

18. The semiconductor structure of claim 17, wherein the first memory cell is connected to a first power line for receiving a first power supply voltage, and a second power line for receiving a second power supply voltage, wherein the first power line and the second power line are positioned at a second interconnect layer disposed over the gate structure.

19. The semiconductor structure of claim 18, wherein one of the first and second source/drain features is electrically coupled to a read bit line, and the read bit line is positioned at the second interconnect layer.

20. The semiconductor structure of claim 17, further comprising a second memory cell, wherein the backside via is further in direct contact with a gate structure of a transistor in a read port portion of the second memory cell.
